(19) United States
(12) Patent Application Publication
(10) Pub. No.: US 2012/0268136 A1
(43) Pub. Date: Oct. 25, 2012

(54) Electrical Test Apparatus

(76) Inventors: Robert Lee, Golden, CO (US); Rodney Hibma, Golden, CO (US)

(21) Appl. No.: 13/459,254

(22) Filed: Apr. 30, 2012

Related U.S. Application Data
(63) Continuation-in-part of application No. 12/390,460, filed on Feb. 21, 2009, now abandoned.
(60) Provisional application No. 61/066,477, filed on Feb. 21, 2008.

(51) Int. Cl. G01R 31/00

(52) U.S. Cl. 324/508

(57) ABSTRACT

Broadly, the present invention is an electrical test apparatus that is adapted to be removably engaged and in electrical communication with an electrical power terminal, the electrical test apparatus includes analytical circuitry that is operative in each of a plurality of modes to monitor the electrical power terminal and produce a plurality of event marker signals. Further included is a criterion circuitry that is operative in each of the plurality of modes to receive each of the plurality of event marker signals for a comparison with a selected value for each of the plurality of modes, wherein the criterion circuitry outputs a plurality of perceptive signals each corresponding to one of the plurality of modes. In addition, a structure is included for producing an associated perceptible output in response to each of the plurality of perceptive signals.

### RELATED PATENT APPLICATIONS

This is a continuation in part (CIP) patent application of U.S. patent application Ser. No. 12/390,460 filed on Feb. 21, 2009 by Rodney Hibma et al. of Golden, Colo. US, that in turn claims benefit of U.S. provisional patent application Ser. No. 61/066,477 filed on Feb. 21, 2008 by Rodney Hibma of Golden, Colo. US, Robert Lee of Golden, Colo. US, Ammon Balaster of Boulder, Colo. US, and Jeffrey Buske of Las Vegas, Nev. US.

### TECHNICAL FIELD

The present invention generally pertains to the field of electrical circuit test apparatus and more particularly to a portable plug-in electrical power line test module electrical circuit tester, including a power line analyzer with the electrical test apparatus adapted to removably engage a common electrical power receptacle. Test examples would include to analyze power line voltages, neutral, ground circuit conditions, and phase rotation.

### BACKGROUND OF INVENTION

Portable electrical power analyzers exist in many sizes and shapes and typically have a single test function or a relatively few test functions available while having numerous adaptive interfaces with the circuit to be tested such as clips, prongs, probes, plugs, and the like. There are a wide variety of electrical power receptacles found throughout households, commercial, and industrial locations. Further, every room in a household or commercial location is provided with multiple receptacles so as to minimize the need for extension cords, and plug adapters that enable multiple loads to be run through a single receptacle in addition to the increased safety hazard of wires running all over like spaghetti, that can cause tripping risk, wire tracing difficulties, unintended flux line interference, and the like. In industrial applications for example, there is electrical equipment that has a high sensitivity to having a good electrical power source that utilize high-power single and three phase power receptacles thus having higher voltages and higher current (amp) levels when these circuits are “live”, resulting in an even greater risk of personal injury or fire risk due to the higher power levels having an equipment damaging potential during a shorted circuit. Thus, accurate testing after a new electrical circuit installation is very important, resulting in all electrical receptacles required to be tested to ensure proper wiring, routing, and grounding prior to the application of electrical power to the circuitry. More specifically, in order to meet local and national code requirements, typical receptacles must have the proper polarity and must be properly grounded. In addition for proper operation of electrical equipment and to help prevent costly damage to electrical equipment and the fire risk, it is imperative that the quality and condition of the power at the receptacle remain within proper voltage limit specifications.

Currently, to test for proper wiring, typically an electrician or an electrical inspector employs a simple receptacle testing device such as a Model #61-500 made by the IDEAL® company to ascertain if the receptacle is wired correctly. To test the condition of the power itself, more expensive multi-testers, both digital and analog are used. To test the condition of the electrical power with a multi-tester, electricians, and individuals who are semi-familiar in the art are required to probe multiple socket terminals of the power receptacle and make numerous voltage measurements, wherein it is difficult for an individual to know all of the different receptacle configurations and their respective electrical power requirements. The probing and multiple measurements are difficult to complete in certain receptacle locations and these voltage measurements alone do not provide a complete analysis of the power or the circuit conditions. As an example, neutral and ground connections are often not tested due to inconvenience. In addition, rotation of three-phase circuits are also generally not tested. To detect these often illusive fault conditions, expensive data loggers and oscilloscopes need to be used to track the condition of the electrical power being provided over a period of time.

In looking at the prior art in this area starting with United States patent application publication number 2008/0204034 to Blades disclosed is an automated electrical wiring inspection system that enables an individual electrician to test every electrical wire, connection, outlet, switch, light, and appliance in a house, typically in a few hours or less. In Blades, the electrician attaches the device to the breaker panel or service panel, and then moves through the house, building, etc, turning power off and on. The system in Blades comprises a Portable Circuit Analyzer that is connected to the building's breaker panel. The circuit analyzer in Blades is in wireless communication with a hand-held computer device, such as a PDA, provided with custom software according to the invention. The circuit analyzer in Blades measures the resistance and length of each circuit established. When the testing process in Blades is completed, the PDA is enabled to generate a complete schematic diagram of the building, including, for example, an identification of the branch circuit to which each fixture, outlet, appliance, or other load or connection point is connected, see text page 2, paragraphs 17 and 18. The panel interface couples to a load center or panel in Blades, for the purpose of mapping the entire building circuitry has a quite involved setup with numerous interfaces to connect, basically every single electrical outlet originating from a particular panel and primarily inducing a half wave rectified load to measure wire resistance with respect to ground.

Continuing in this area in the prior art in U.S. Pat. No. 7,259,567 to Sears et al., disclosed is an electrical outlet testing apparatus that can be connected to electrical outlets of various amperages, typically taught as 20, 30, and 50 amp circuits. The apparatus in Sears et al., includes an exterior body with a front and rear surface or panel, on the rear surface or panel, there is at least one electrical contact member for receiving an electrical signal when connected to the outlet. A processor unit in Sears et al., receives the signal and determines whether the outlet is wired correctly and producing quality electrical service, wherein quality electrical service means the outlet is producing the correct voltage and current. In Sears et al., depending on how the processor unit interprets the electrical signal, the condition of the outlet is displayed in a visual and audible format on the front surface or panel, see column 1, lines 39-55, with the typical indications being voltage, polarity, and open ground or neutral, wherein the ground integrity system utilizes capacitors in an unbalanced bridge using optoisolators that are in electrical communication with the capacitors.

Further, in the applicable prior art in U.S. Pat. No. 6,323,652 to Collier et al. disclosed is an electrical testing apparatus for determining the continuity between ground terminals of an electrical power extension cord and for determining the electrical grounding of an electrical power tool. The electrical testing apparatus in Collier et al., can also be configured to determining the proper polarity on each of the hot, negative, and ground cord wires of an electrical power extension cord. Each embodiment in Collier et al., generally comprises a plastic case housing one or more batteries which supplies power to a test button and the ground terminal of a female receptacle installed in the case, the one or more batteries are preferably 9 volt batteries, see Column 2, lines 66-67 and Column 3, lines 1-10. Next, in U.S. Pat. No. 6,734,682 to Tallman et al. disclosed is a testing apparatus for detecting and locating arc faults in an electrical system, wherein the typical arcing faults do not usually trip a typical circuit breaker, with the arcing faults caused by loose wire connections or terminations, worn wire insulation, and the like. Furthermore, the testing apparatus in Tallman et al., may be employed to locate electrical conductors and/or to detect one or more faults in an electrical system. Also, the testing apparatus in Tallman et al., may be used in combination with a pulsing device, which produces a periodic arcing signal to cause one or more of the arcing fault characteristics, in order to provide a testing system for detecting and locating an arcing fault in the electrical system, see column 1, lines 39-49. An annunciator speaker or display in Tallman et al., annunciates the responsive signal when the detector circuit is proximate to the arcing fault, in order to locate the arcing fault in the electrical system.

Yet further in the electrical test apparatus prior art in U.S. Pat. No. 6,933,712 to Miller et al., disclosed is an electrical circuit tracing and identifying apparatus and method. To reduce false-positive indications in Miller et al., some embodiments of the present invention transmit and receive a mid-range carrier frequency between 120 Hz and 3900 Hz, using a mid-range carrier frequency reduces coupling to adjacent circuits. Some embodiments in Miller et al., locate a carrier frequency between a pair of adjacent harmonics of the power line frequency, locating a carrier frequency between harmonics of the power line frequency mitigates the confusion receivers have in distinguishing between a transmitted signal and signals generated by other loads, also some embodiments use a time-variant filter. The time-variant filter in Miller et al., integrates over an integral number of power lines cycles to eliminate responses at harmonics of the power of the frequency and to reduce confusion between the transmitted signal and signals generated by other loads. To reduce errors due to erroneous calibration by the electrician in Miller et al., some embodiments of the present invention automatically compare the levels of received signals and by comparing received signal levels, the apparatus automatically calibrates itself. Some embodiments in Miller et al., implement a phase switching process, wherein phase switching helps to concentrate the spectral components of the transmitted signal about the carrier frequency, see column 3, lines 14-49.

What is needed is a compact receptacle tester that is simple and easy to use, being portable, and of a single piece construction that can be plugged into a receptacle as easy as a lamp cord plug, wherein more complete test diagnostics are performed than with currently available basic voltage testers. Desired enhanced test diagnostics would include testing the condition of the voltage level itself, neutral, and ground connections, and rotation of three-phase circuits. Thus, the ideal receptacle test apparatus would include all or a part of the previously mentioned testing capabilities, while at the same time be a small, lightweight, portable, and easy to use apparatus that can perform multiple testing functions. The resultant electrical test apparatus can be plugged into a power receptacle that includes electronic circuitry and a microprocessor to measure voltages across all lines, line to neutral, neutral to ground, and display the resulting power condition and correct or incorrect wiring on a custom read-at-a-glance display by someone with minimal electrical power and circuitry knowledge, without the need to interpret various numerical readouts for determining acceptable electrical test results which requires specialized electrical power and circuitry knowledge and additional time.

Thus the desired electrical test apparatus may be plugged into a power receptacle that includes electronic circuitry and a microprocessor to measure voltages across all lines, line to neutral, neutral to ground, and related parameters, plus display the resulting power condition and correct or incorrect wiring on a custom read-at-a-glance display. The electrical test apparatus can have different plug-in adapters so that the apparatus can be used with any configuration power outlet. Also, a typical embodiment of the apparatus that includes a single or a plurality of lights or LEDs that always are illuminated to indicate correct or incorrect wiring of the outlet and may also indicate high or low voltage, incorrect ground connection, as well as rotation direction if used in three phase circuits, among other things.

### SUMMARY OF INVENTION

Broadly, the present invention is an electrical test apparatus that is adapted to be removably engaged and in electrical communication with an electrical power terminal. Due to the complexity and sensitivity of electronic equipment in the market, electrical voltage testing procedures for different types of electrical power outlet receptacles have become more necessary, especially those with more sensitive electronic equipment, such as server farms. A simple device that is currently used is a digital voltmeter to read the actual voltage at a point of contact of an electrical receptacle. However, it takes someone familiar in the power electrical arts to know if the value read on the meter is appropriate for the particular point of an electrical outlet, especially given the great variety of electrical receptacles, and when there exists a specialized receptacle like a twist lock type, including three phase, even those familiar in the electrical power arts may not be familiar enough. Even with tools currently on the market to make a power check easy for those not familiar in the art there can be situations that can cause the equipment to fail from electrical power not being within specifications.

There is a plug tester for checking the NEMA 5-15 receptacle, the common household receptacle in America, that tells whether the outlet has power and whether it is wired correctly. There have been cases encountered where that type of receptacle was incorrectly electrically connected to 277 volts and had that tester light up normally with the same light intensity and not have the tester damaged, thus indicating an OK circuit, when in fact it should have been 120 volts. This has resulted in equipment catastrophically failing that was electrically connected to that outlet before the problem was discovered. Of course, any equipment, especially electronic equipment, designed to be connected to 120 volts plugging into that too high of voltage.

There remains the need for an electrical test apparatus that is designed to be more of a “fail safe” device in operation, thus always affirmatively indicating acceptable electrical parameters have been meet and to always affirmatively indicate whenever unacceptable test results occur. This means that a light just simply cannot indicate the presence of voltage (which could be too high or too low) or having a “no light on” condition to indicate a particular operational state-wherein it would not be known in the particular operational state was meeting or just that the circuitry or light was inoperative, thus there needs to be a specific colored light for each one of many anticipated electrical conditions. Thus, simply “Green illuminated is good. Not green (having another color indication illuminated), being not good” is desirable for an affirmative electrical condition indication.

The present invention utilizes a programmable circuit board that has been developed for utilizing multiple changing color single LEDs as indicators to determine voltage levels at several points simultaneously and at a quick and easy glance convey that information to the electrical test apparatus user. The typical light indicators are green for within a nominal voltage range, yellow for lower and red for above range or out of range. This is accomplished by measuring the peak of a sine wave and comparing it to predetermined and programmable values in a microprocessor register. It has been used in a receptacle tester for a great variety of single and three phase receptacles, but can also be used to monitor voltages of an electrical system by anyone, not only those familiar in the electric power arts.

A test procedure for a 120 volt nominal typical system would show the following results. The circuit board would have three input wires and three functioning LED's. The circuit board would be programmed to respond to these 3 input wires only. When the circuit board is connected to a variable 120 volt alternating current (VAC) source, the board would expect to see voltage between the hot (L1) and neutral (N), voltage between the hot (L1) and ground (G) and no voltage between the neutral (N) and ground (G). The programmed values in the microprocessor register would be set at 100 volts minimum and 125 volts maximum for L1 to either N or G, and a maximum of 5 volts for the N to G. As the test starts at 0 volts and increases, the LED's would be off until approximately 60 volts is reached when the LED's for L1 and N will turn yellow indicating electrical power available but below an acceptable range, and the G LED would be green since there is less than 5 volts between N and G. When the voltage increases to 100 volts all the LED's turn green since everything is now within the acceptable range. When the voltage continues to increase to 125 volts, L1 and N LED's turn red since they are now over range with the G LED still green. If L1 and N are switched and the same procedure followed, the G LED would turn red because you would have greater than 5 volts between the neutral (N) and the ground (G) points, indicating an electrically defective fault condition resulting from incorrectly wired connections.

If this test could be expanded to include a second and third electrical phase, there would need to be additional LED's to respond to L2 and L3, as being two added hot electrical power lines to the original L1. The voltage points to be measured would be L1-L2, L1-L3, L2-L3, L1-N, L2-N, L3-N and N-G. Five LED's are utilized to represent each of the five conductors one for one. The microprocessor register would be changed to determine the L1, N, and G voltages and include line to line voltage ranges with L2 and L3 to N. The parameters for a 208VAC/120VAC wye type three electrical (NEMA 21) phase configuration would have a 200 volt minimum threshold and a 215 volt maximum threshold for the nominal line to line voltage setting. There would be a problem if this circuit board would be connected to a 240 volt delta type three electrical phase configuration high leg system as this would turn all but the N-G connection red, but the circuit board can be programmed to accept higher voltages which would allow the user to verify all voltages are acceptable except for the L2-N (high leg) connection which would make the N LED turn red. The circuit board is also capable of sensing voltage rotation. When the rotation is clockwise, the phase LED's will illuminate colors continuously according to the voltages they read. Should the rotation be counter clockwise, the phase LED's will illuminate colors according to the voltage level, but the LED's will flash.

These and other objects of the present invention will become more readily appreciated and understood from a consideration of the following detailed description of the exemplary embodiments of the present invention when taken together with the accompanying drawings, in which;

### BRIEF DESCRIPTION OF DRAWINGS

FIG. 1 shows a perspective view of the electrical test apparatus with a first end portion of a housing facing frontward with an adaptor for different multiple prong connections for a plurality of unique multiple prong groups that show a multiple prong connector of a twist lock type, further an opposing second end portion of the housing is shown;

FIG. 2 shows an opposing perspective view of the electrical test apparatus from FIG. 1, with FIG. 2 showing a second end portion facing frontward of the housing with either a single always status indicating illuminated LED light or alternatively a plurality of always status indicating illuminated LED lights, plus the first end portion of the housing facing rearward, that shows a multiple prong connector of a twist lock type;

FIG. 3 shows an exploded perspective view of the electrical test apparatus with the housing separated showing the circuit board with the first end portion of the housing facing frontward with an adaptor for different multiple prong connections for a plurality of unique multiple prong groups that show a multiple prong connector of a twist lock type, further a second end portion of the housing facing rearward is shown with either a single always illuminated LED light or alternatively a plurality of always status indicating illuminated LED lights, along with a means for electrical test apparatus activation/deactivation;

FIG. 4 shows a summary schematic of the electrical test apparatus wherein the housing envelope is shown, with a power receptacle, a power receptacle adapter, a high voltage attenuator, a microprocessor, a memory, analog to digital converters, a power supply, and display;

FIG. 5 shows a detailed schematic for the electrical test apparatus of an alternating current input schematic of the circuit board with a high voltage module input, with fuses, diodes, and with voltage attenuating resistors of the high voltage module with processor inputs that form a part of a analytical circuitry and criterion circuitry;

FIG. 6 shows a detailed schematic of the programming input circuitry of the circuit board for the processor programming inputs of the electrical test apparatus;

FIG. 7 shows a detailed schematic of the processor portion of the circuit board of the electrical test apparatus with the analytical circuitry, the criterion circuitry, a perceptive circuitry, processor input, processor programming input, a reference voltage input, and the perceptible output in the form of the single always status indicating illuminated LED multi color light, or alternatively a plurality of always status indicating illuminated LED lights that each are multi color lights;

FIG. 8 shows a detailed schematic of the direct current battery power circuitry portion of the circuit board for the electrical test apparatus showing the reference voltage input and a direct current input regulator;

FIG. 9 shows a description of the connection definitions for NEMA plug configurations that the circuit board can be programmed to monitor;

FIG. 10 shows a printed circuit board layout portion of the electrical test apparatus including the high voltage input, the analytical circuitry, the criterion circuitry, the high voltage module, the direct current input regulator, single always status indicating illuminated LED light, and the programmable chip;

FIG. 11 shows a use or installed view of the electrical test apparatus, with the second end portion facing frontward of the housing with either a single always status indicating illuminated LED light, or alternatively a plurality of always status indicating illuminated LED lights plus the first end portion of the housing facing rearward, that shows a multiple prong connector of a twist lock type that is inserted into an electrical power terminal of the electrical power receptacle, wherein the multiple prong connector that is a twist lock type that is removably engaged to the electrical power receptacle; and

FIG. 12 shows a table of the NEMA configurations, with nominal voltages, phases, and various voltage thresholds for the yellow, green, and red always status indicating illuminated LED lights.

### REFERENCE NUMBERS IN DRAWINGS

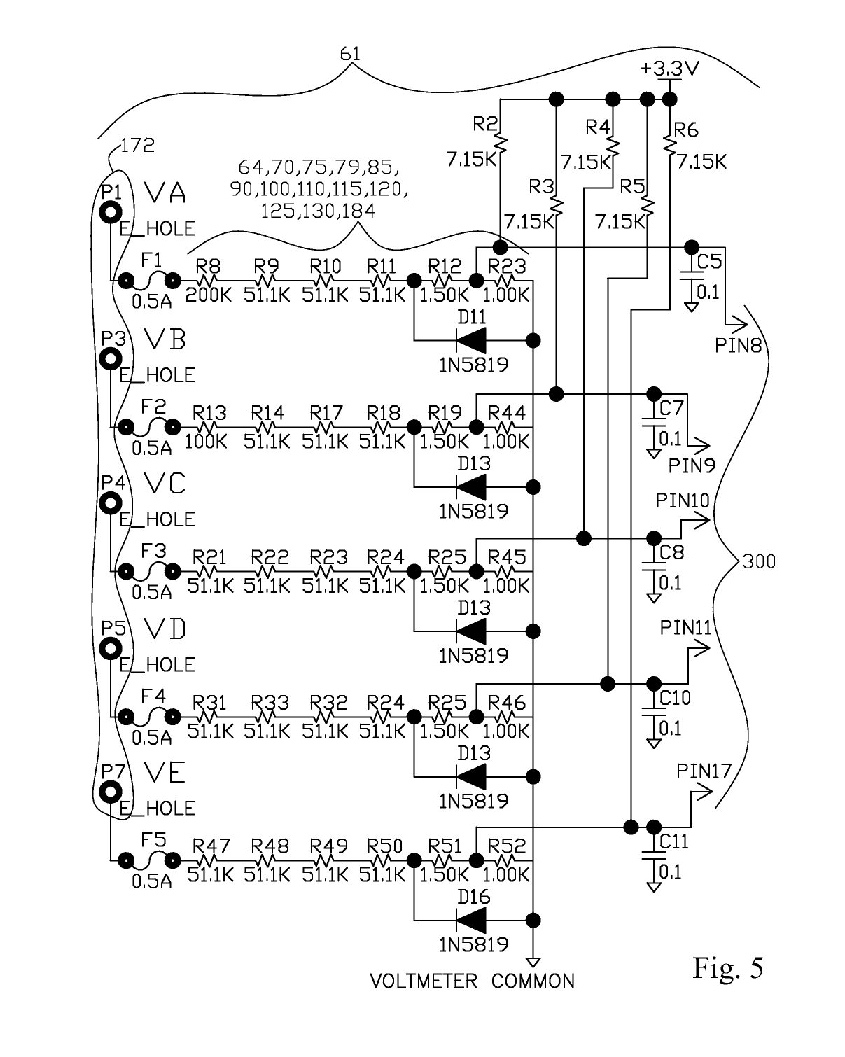

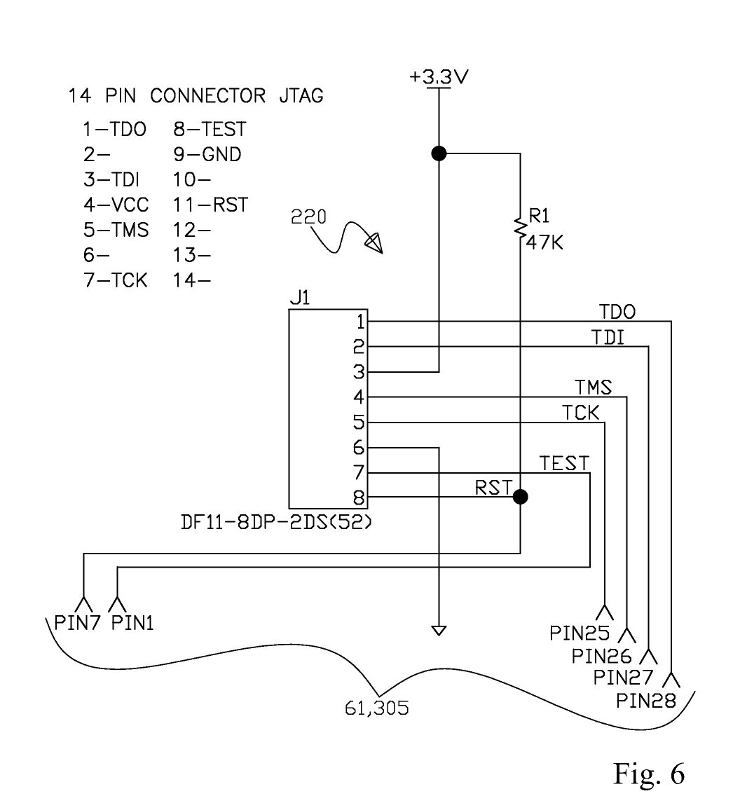

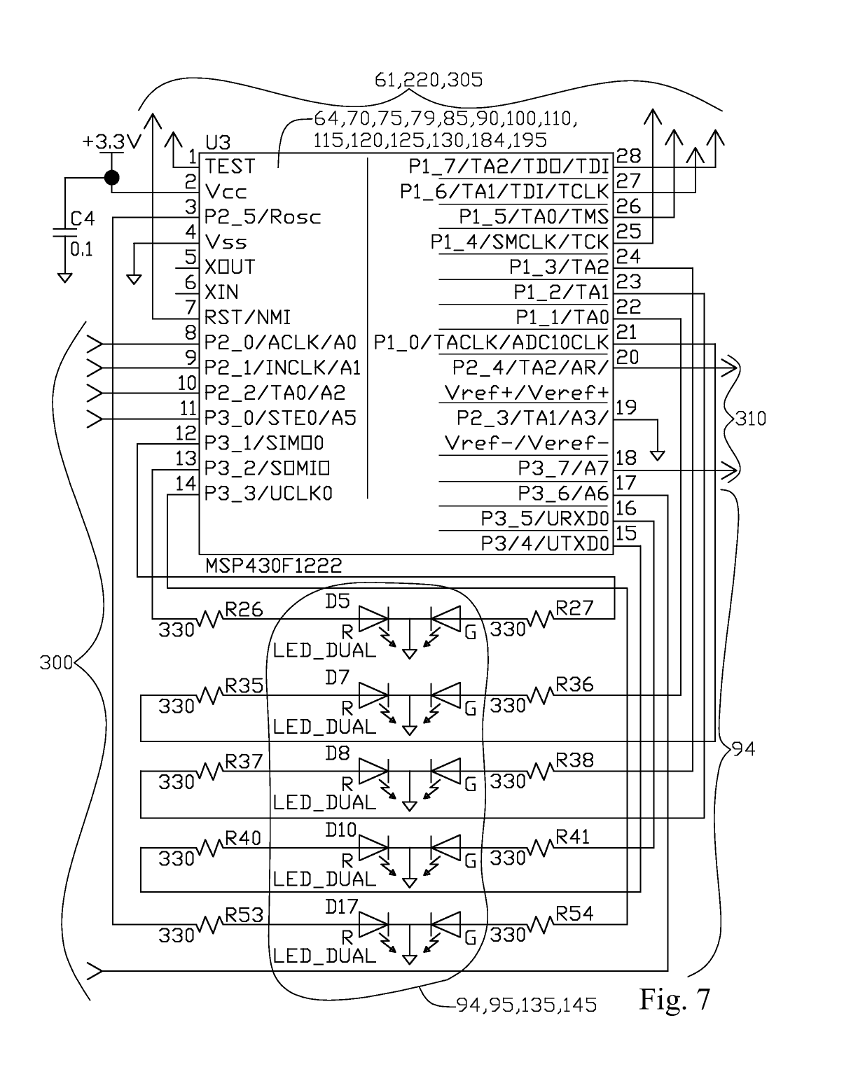

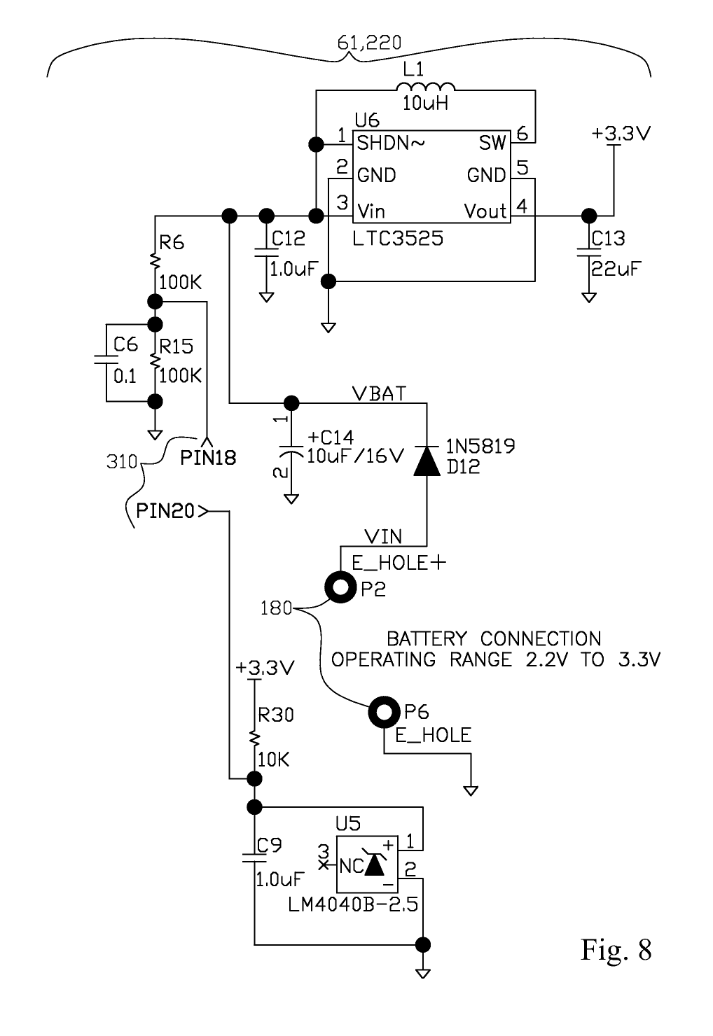

50 Electrical test apparatus
55 Electrical power terminal to receptacle 56
56 Electrical power receptacle
60 Adapted to be removably engaged and in electrical communication between the electrical test apparatus 50 and the electrical power terminal 55
61 Circuit board
64 Attenuation/analytical circuitry
70 Plurality of modes of the analytical circuitry 64
75 Event marker signals of the analytical circuitry 64
79 Criterion circuitry
85 Selected value of the criterion circuitry 79
90 Plurality of perceptive signals of the criterion circuitry 79
94 Perceptive circuitry including a single always status indicating illuminated LED light illuminated LED multi color light 95
95 Single always status indicating illuminated LED multi colored light
100 Voltage mode
110 Three phase circuit rotations mode
115 Ground conditions mode
120 Neutral conditions mode
125 Circuit tracers mode
130 Frequencies signals mode
135 Visual display of the single always status indicating illuminated LED multi color light 95 or alternatively a plurality of always status indicating illuminated LED lights that are each a multi colored light 95
140 Plurality of LED lights 95 of the visual display
145 Unique color(s) of the plurality of LED lights
155 Housing of the electrical test apparatus 50
160 First end portion of the housing 155
165 Second end portion of the housing 155
169 Multiple prong connector
170 Multiple prong connector 169 of a twist lock type
171 Adapter for different multiple prong connections and the identification feature alternative embodiment
172 High voltage input
176 Memory
179 Energy source or battery
180 Storage power circuitry for a direct current input regulator from the energy source or battery 179
184 High voltage module
189 Analog/digital convertor
195 Programmable chip
200 Plurality of unique multiple prong groups
205 Pin and sleeve type multiple prong connector
210 Means for electrical test apparatus activation/deactivation that is operational based upon proximity of the first end portion 160 to the electrical receptacle 56
220 Programming input circuitry
300 Processor input schematic interconnect from FIG. 5 to 7
305 Processor programming inputs schematic interconnect from FIG. 6 to 7
310 Reference voltage input schematic interconnect from FIG. 7 to 8

### DETAILED DESCRIPTION

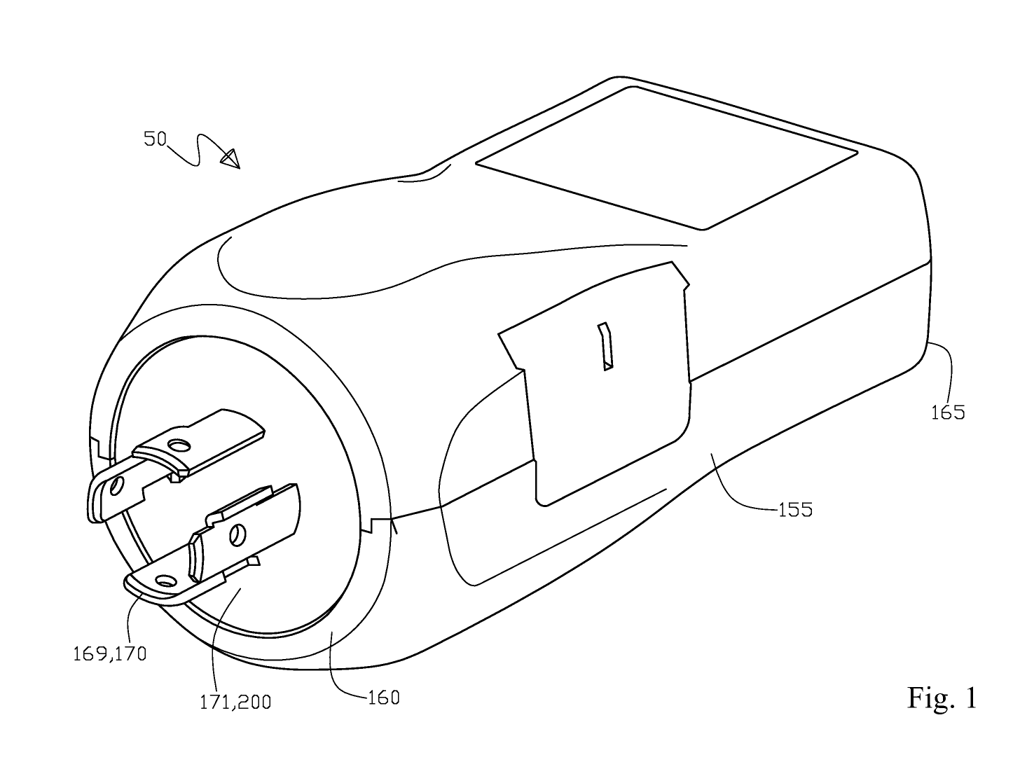

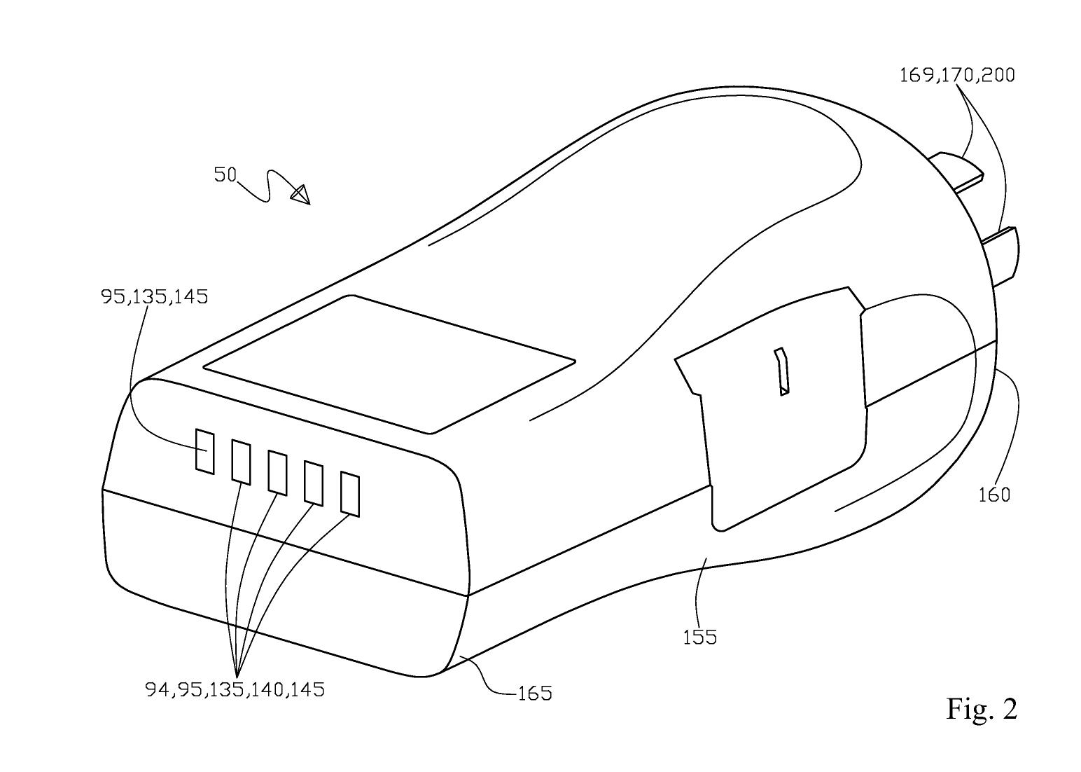

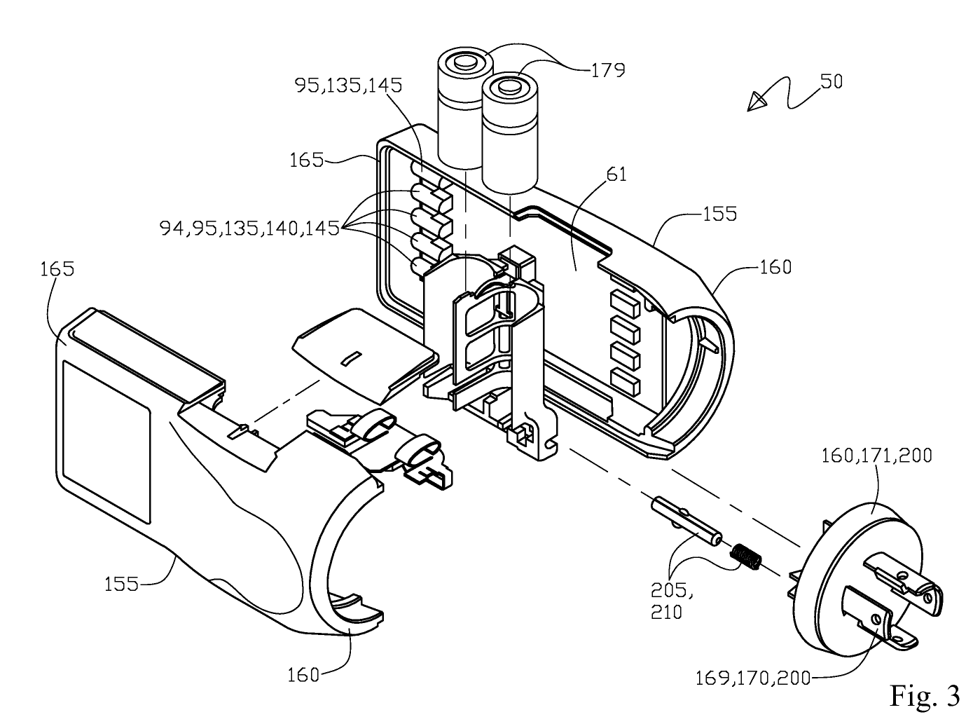

With initial reference to FIG. 1 shown is a perspective view of the electrical test apparatus 50 with the first end portion 160 of the housing 155 facing frontward with an adaptor 171 for different multiple prong connections 169 for a plurality of unique multiple prong groups 200, that show a multiple prong connector of a twist lock type 170, further the second end portion 165 of the housing 155 is shown. Continuing, FIG. 2 shows an opposing perspective view of the electrical test apparatus 50 from FIG. 1, with FIG. 2 showing a second end portion 165 facing frontward of the housing 155 with the visual display 135 of either the single always illuminated LED light 95 or alternatively a plurality of always status indicating illuminated LED lights 140 plus the first end portion 160 of the housing 155 facing rearward, that show a multiple prong connector 169 of a twist lock type 170. Next, FIG. 3 shows an exploded perspective view of the electrical test apparatus 50 with the housing 155 separated showing the circuit board 61, the power supply electrical energy source 179, with the first end portion 160 of the housing 155 facing frontward, with an adaptor 171 for different multiple prong connections 169 for a plurality of unique multiple prong groups 200, that show a multiple prong connector of a twist lock type 170, further the second end portion 165 of the housing 155 facing rearward is shown with either a single always status indicating illuminated LED light 95 or alternatively a plurality of always status indicating illuminated LED lights 140.

### Neutral Ground Status

Indicator 95 indicates status of the neutral, green on-good, red on-overvoltage condition (neutral is “hot” i.e. greater than 5V), red off-open state, (when the multiple prong connector adaptor 169 or 170 has neutral pin or ground pin), single flashing red-low battery 179 voltage, multiple indicators 95 flashing red-three phase overvoltage counter clockwise phase rotation.

The present electrical test apparatus 50 invention helps to advance the state the circuit analyzer art with a compact and portable measurement tool that with quickly and safely connects to any standard circuit receptacle 56. The electrical test apparatus 50 performs in near real time about thirteen circuit measurements, being as an example for including but not limited to:

### Open Ground

### Hot Ground

Open neutral
Hot neutral

### Rotation

### Delta/wye Circuit

Nominal Line voltage

### A-Line to Neutral

### B-Line to Neutral

### C-Line to Neutral

A-C Line to line
A-B Line to line
B-C Line to line

Thus the electrical test apparatus 50 is a small rugged pocket sized unit that is easy to use and read by most any user, even a user with very limited electrical experience.

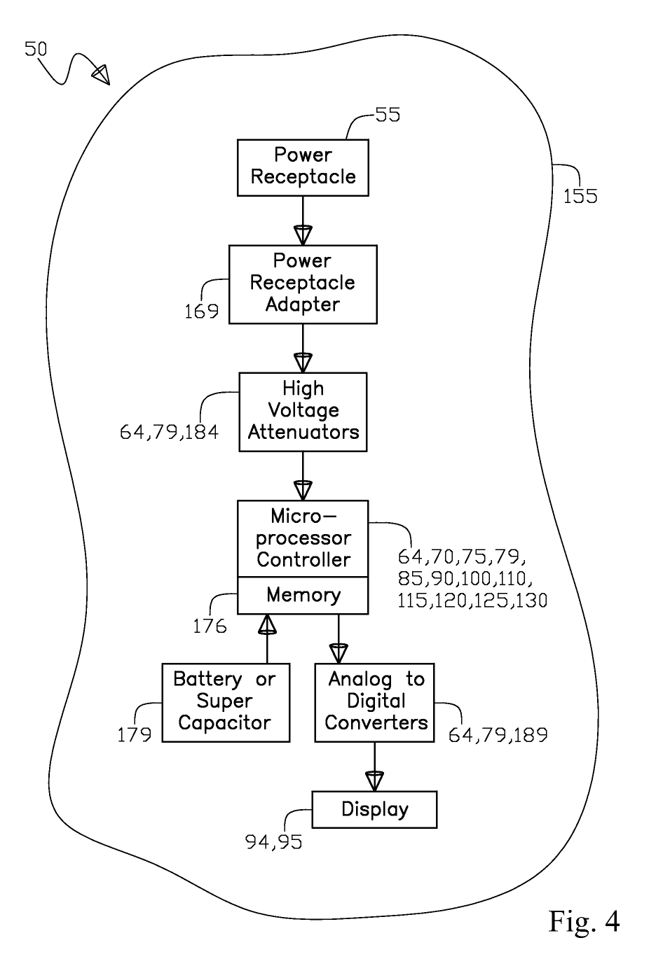

Continuing, FIG. 4 shows a summary schematic of the electrical test apparatus 50 wherein the housing 155 envelope is shown, with a power receptacle 55, a power receptacle adapter 169, a high voltage attenuator 64, 79, 184, a microprocessor 64, 70, 75, 79, 85, 90, 100, 110, 115, 120, 125, 130, 184 a memory 176, a power supply 179, analog to digital converters 64, 79, 189 and display 94, 95. Next, FIG. 5 shows a detailed schematic for the electrical test apparatus 50 of primarily an alternating current input schematic portion of the circuit board 61 with a high voltage module 64, 79, 184 input 172, with fuses, diodes, and voltage attenuating resistors of the high voltage module shown with processor inputs 300 that form a part of the analytical circuitry 64 and criterion circuitry 79.

Continuing, FIG. 6 shows a detailed schematic of the programming input circuitry 220 of the circuit board 61 for the processor programming inputs 305 of the electrical test apparatus 50. Next, FIG. 7 shows a detailed schematic of the processor portion with the programmable chip 195 of the circuit board 61 of the electrical test apparatus 50 with the analytical circuitry 64, the criterion circuitry 79, the perceptive circuitry 94, the processor input 300, processor programming input 305, a reference voltage input 310, and the perceptible output in the form of the single always status indicating illuminated LED multi color light 95, or alternatively a plurality of always status indicating illuminated LED lights 140 that each are multi color lights. Further, FIG. 8 shows a detailed schematic of the direct current battery 179 power circuitry portion 180 of the circuit board 61 for the electrical test apparatus 50 showing the reference voltage input 310 and a direct current input regulator 180.

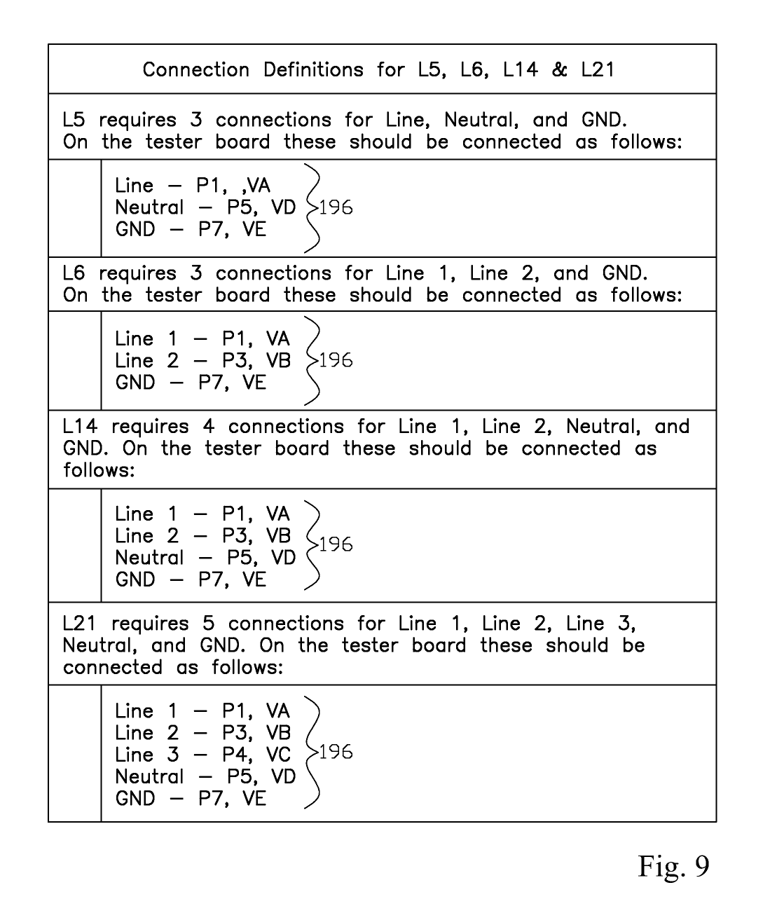

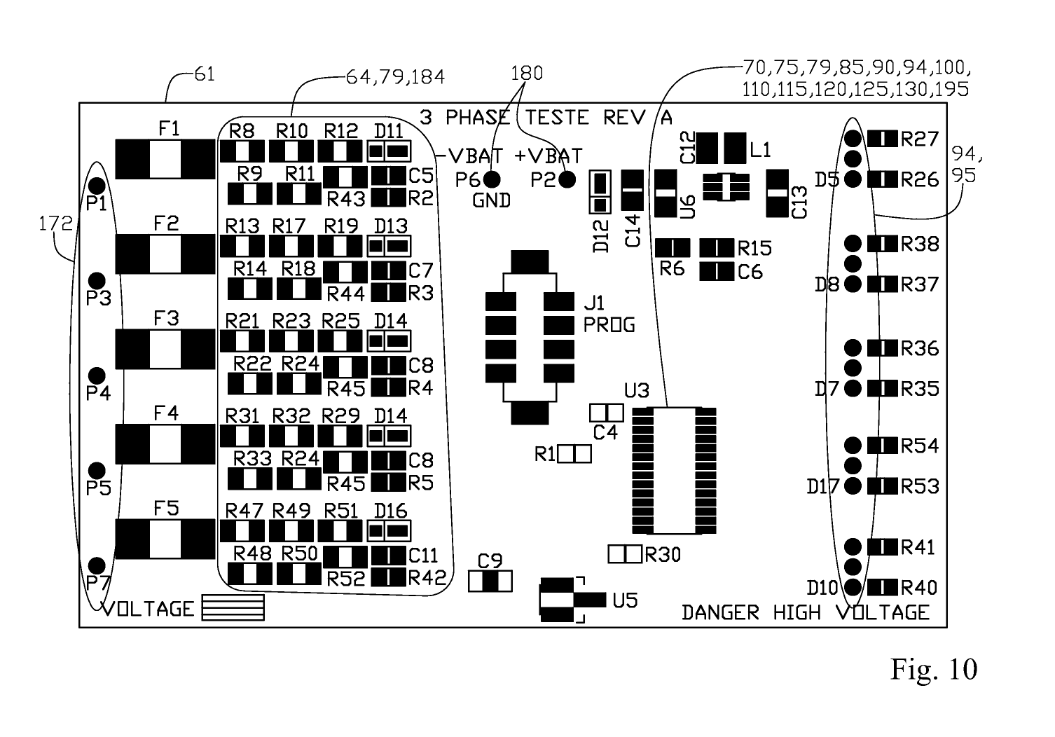

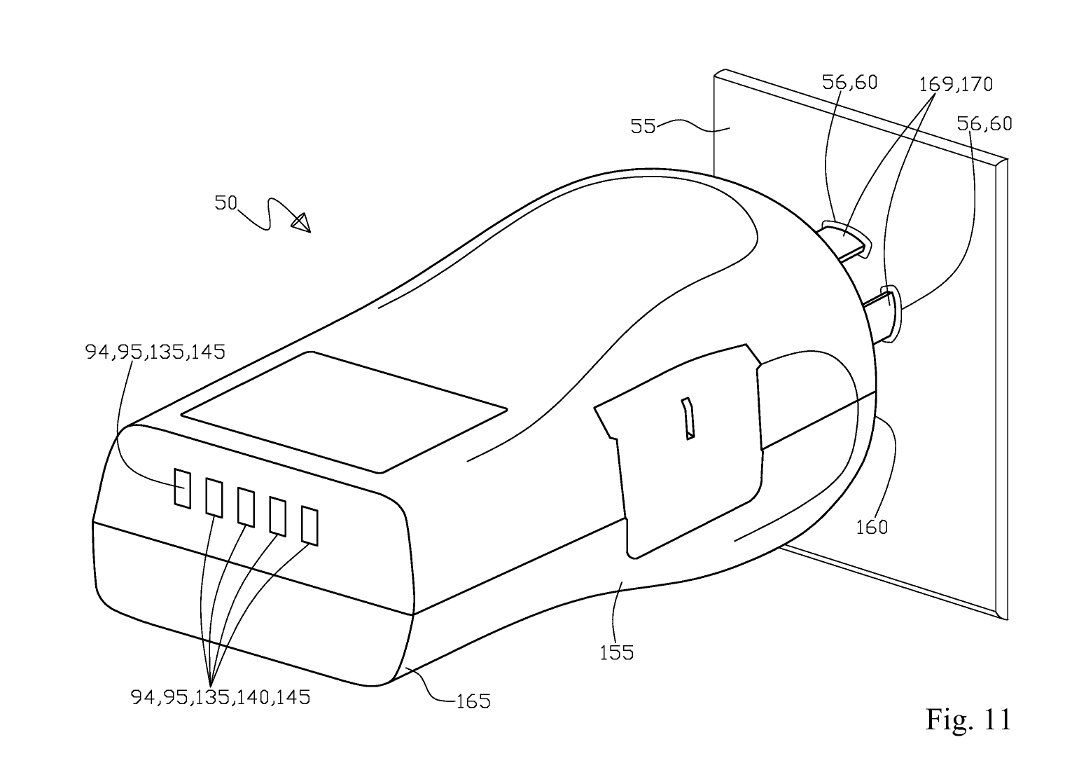

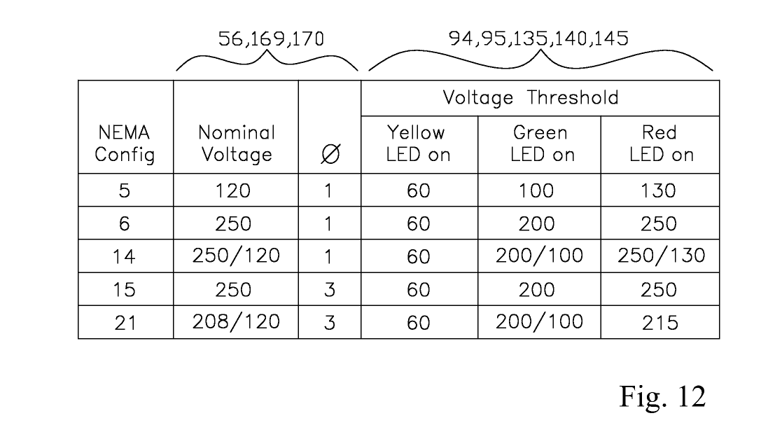

Next, FIG. 9 shows a table of the connection definitions for NEMA plug configurations that the circuit board 61 can be programmed to monitor. Continuing, FIG. 10 shows a printed circuit board 61 layout portion of the electrical test apparatus 50 including the high voltage input 172, the attenuation circuitry 64, the criterion circuitry 79, the high voltage module 184, the direct current input regulator 180, single always status indicating illuminated LED light 95, and the programmable chip 195. Further, FIG. 11 shows a use or installed view of the electrical test apparatus 50, with the second end portion 165 facing frontward of the housing 155 with either a single always illuminated LED light 95 or alternatively a plurality of always status indicating illuminated LED lights 140. Plus, FIG. 11 shows the first end portion 160 of the housing 155 facing rearward, that shows a multiple prong connector 169 of a twist lock type 170 that is inserted into an electrical power terminal 55 of the electrical power receptacle 56, wherein the multiple prong connector 169 that is a twist lock type 170 that is removably engaged 60 to the electrical power receptacle 56. Further, FIG. 12 shows a table of the NEMA configurations, with nominal voltages, phases, and various voltage thresholds that are present at the electrical power receptacle 56 or multiple prong connectors 169 and 170 for the yellow, green, and red always status indicating illuminated LED lights 94, 95, 135, 140, and 145.

The power input circuitry 220 is preferably constructed of a main component power module by Hirose model DF11G-8DP-2V(50) or equivalent, as best shown in FIG. 6.

Broadly, the present invention of the electrical test apparatus 50 is adapted to be removably engaged 60 and in electrical communication 60 with an electrical power terminal 55, which could be a wire cable connection or any other equivalent, as best shown in FIGS. 1, 2, and 11. The electrical test apparatus 50 includes analytical circuitry 64 that is operative in each of a plurality of modes 70 that include voltages 100 having line to line, line to neutral, and neutral to ground voltage differential measurements, three phase circuit rotations 110, ground conditions 115, and neutral conditions 120, to monitor the electrical power terminal 55. Thus, the analytical circuitry 64 being operative to produce a plurality of event marker signals 75 that are each associated with each of the plurality of modes 70.

Referencing FIGS. 3 through 10, further included in the electrical test apparatus 50 is criterion circuitry 79 that is operative in each of the plurality of modes 70 that include voltages 100 having line to line, line to neutral, and neutral to ground voltage differential criterion set points 85, three phase circuit rotations 110, ground conditions 115, and neutral conditions 120, to receive each of the plurality of event marker signals 75 for a comparison with a nominal standard value 85 stored in a memory 176 with a deviation criteria 85 for each of the plurality of modes 70. Wherein the criterion circuitry 79 outputs a plurality of perceptive signals 90 for each of the plurality of modes 70 based on a pass, caution, or fail deviation from each said nominal standard 85 for each one of the plurality of modes 70.

Also included in the electrical test apparatus 50 is perceptive circuitry 94 that includes a single always status indicating illuminated light 95, wherein the perceptive circuitry 94 enables the single always status indicating illuminated light 95 to indicate at least three different operational states of each one of the modes 70. Wherein the perceptive circuitry 94 receives each of the plurality of perceptive signals 90 for each of the plurality of modes 70, resulting in the perceptive circuitry 94 being in electrical communication with and responsive to a corresponding one of the plurality of perceptive signals 90 for each of the plurality of modes 70. Wherein operationally a user can easily access electrical test results via looking at the single always status indicating illuminated light 95.

In the above embodiment of the electrical test apparatus 50 it is possible to have a single always illuminated light 95 accommodate a plurality of modes 70 by switching mode by mode to the single light 95, as the single light 95 can indicate three or more electrical operational conditions for a selected mode 70, however, always requiring light 95 illumination, even though the light 95 may be momentarily off, it is always on to indicate an electrical status condition, leaving no questions as to the electrical condition that is being monitored, as opposed to an off light indicating a condition, that may be the result of an open circuit instead of the purported off light condition.

Further, on the electrical test apparatus 50, the perceptive circuitry 94 is configured to create the at least three different operational states of the single always status indicating illuminated light 95 by preferably utilizing different illuminated colors for the single always status indicating illuminated light 95, see in particular FIGS. 2 and 7. Continuing, on the electrical test apparatus 50 also for the perceptive circuitry 94, it can be configured to create the at least three different operational states of the single always illuminated status indicating illuminated light 95 by utilizing different flashing rates or frequencies for the single always illuminated light 95 to indicate different electrical operating conditions, or optionally can be combined with the different colors having different blinking rates or frequencies to convey a multitude of electrical operating conditions with a single light 95.

Continuing on the electrical test apparatus 50 for the perceptive circuitry 94 that includes the single always status indicating illuminated light 95 set, can be optionally provided as a plurality of perceptive circuitry 94 that includes the single always status indicating illuminated light 95 sets, with each one of the perceptive circuitry 94 and single illuminated light 95 sets in electrical communication with each one of the plurality of perceptive signals 90 for each of the plurality of modes 70. Thus to operationally dedicate each one of the perceptive circuitry 94 that includes the single always status indicating illuminated light 95 set to each one of the modes 70.

Also, in looking at FIGS. 1 through 3, on the electrical test apparatus 50 the analytical circuitry 64, the criterion circuitry 79, and the perspective circuitry can all be disposed within a housing 155. Wherein the housing 155 on the electrical test apparatus 50 can further have a first end portion 160 and a second end portion 165, with the first end portion 160 being adjacent to a multiple prong connector 169 that is removably engagable 60 and in electrical communication with an electrical receptacle 56 and the second end portion 165 is adjacent to the single always status indicating illuminated light 95 or alternatively a plurality of lights 140 with the associated plurality of perceptive circuitry 94.

Continuing, on the electrical test apparatus 50 for the multiple prong connector 170, can be a plurality of unique multiple prong groups, wherein each multiple prong group is associated with the criterion circuitry 79 having a nominal standard value 85 stored in the memory 176 with deviation criteria defined by each unique multiple prong group for each mode 70.

Preferably the lights 95 are Panasonic model dual LED LN11WP23 or equivalent.

Wherein the analytical circuitry 64 and the criterion circuitry 79 are typically embodied in a programmable chip 195 that further includes the analog/digital converter 189 that is preferably a Texas Instruments MSP430F1222IPW or equivalent.

### CONCLUSION

Accordingly, the present invention of an electrical test apparatus has been described with some degree of particularity directed to the embodiments of the present invention. It should be appreciated, though, that the present invention is defined by the following claims construed in light of the prior art so modifications or changes may be made to the exemplary embodiments of the present invention without departing from the inventive concepts contained therein.

1. An electrical test apparatus that is adapted to be removably engaged and in electrical communication with an electrical power terminal, said electrical test apparatus comprising:
(a) analytical circuitry operative in each of a plurality of modes that include voltages having line to line, line to neutral, and neutral to ground, three phase circuit rotations, ground conditions, and neutral conditions, to monitor the electrical power terminal and operative to produce a plurality of event marker signals that are each associated with each of said plurality of modes;
(b) criterion circuitry operative in each of said plurality of modes that include voltages having line to line, line to neutral, and neutral to ground, three phase circuit rotations, ground conditions, and neutral conditions, to receive each of said plurality of event marker signals for a comparison with a nominal standard value stored in a memory with a deviation criteria for each of said plurality of modes, wherein said criterion circuitry outputs a plurality of perceptive signals for each of said plurality of modes based on a pass, caution, or fail deviation from each said nominal standard for each one of said plurality of modes; and
(c) perceptive circuitry that includes a single always status indicating illuminated light, said perceptive circuitry enables said single always status indicating illuminated light to indicate at least three different operational states of each one of said modes, wherein said perceptive circuitry receives each of said plurality of perceptive signals for each of said plurality of modes, resulting in said perceptive circuitry being in electrical communication with and responsive to a corresponding one of said plurality of perceptive signals for each of said plurality of modes, wherein operationally a user can easily access electrical test results via looking at said single always status indicating illuminated light.

2. An electrical test apparatus according to claim 1 wherein said perceptive circuitry is configured to create said at least three different operational states of said single always status indicating illuminated light by utilizing different illuminated colors for said single always status indicating illuminated light.

3. An electrical test apparatus according to claim 1 wherein said perceptive circuitry is configured to create said at least three different operational states of said single always status indicating illuminated light by utilizing different flashing rates for said single always illuminated light.

4. An electrical test apparatus according to claim 1 further comprising a plurality of said perceptive circuitry that each include a single always status indicating illuminated light with each one of said perceptive circuitry and single illuminated light sets in electrical communication with each one of said plurality of perceptive signals for each of said plurality of modes to operationally dedicate each one of said perceptive circuitry that includes a single always status indicating illuminated light to each one of said modes.

5. An electrical test apparatus according to claim 1 wherein said analytical circuitry, said criterion circuitry, and said perspective circuitry are all disposed within a housing.

6. An electrical test apparatus according to claim 5 wherein said housing has a first end portion and a second end portion, said first end portion is adjacent to a multiple prong connector that is removably engagable and in electrical communication with an electrical receptacle and said second end portion is adjacent to said single always status indicating illuminated light.

7. An electrical test apparatus according to claim 6 wherein said multiple prong connector is a plurality of unique multiple prong groups, wherein each multiple prong group is associated with said criterion circuitry having a nominal standard value stored in said memory with deviation criteria defined by each said unique multiple prong group for each said mode.
